(19) United States
(12) Patent Application Publication
(10) Pub. No.: US 2007/0002969 A1
(43) Pub. Date: Jan. 4, 2007

(54) Transmitting/receiving apparatus and method in a mobile communication system

(75) Inventors: Su-Ryong Jeong, Suwon-si (KR); Sung-Kwon Hong, Seoul (KR); Young-Kwon Cho, Suwon-si (KR); Jung-Min Ro, Seoul (KR); Young-Kyun Kim, Seongnami-si (KR); Dong-Seek Park, Yongin-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., Suwon-si (KR)

(21) Appl. No.: 11/450,495

(22) Filed: Jun. 9, 2006

(30) Foreign Application Priority Data
Jun. 9, 2005 (KR) 2005/0049178

(51) Int. Cl. H04L 27/36; H04L 27/20; H03D 1/24

(52) U.S. Cl. 375/298; 375/308; 375/320

(57) ABSTRACT

A transmitting/receiving apparatus and method in a mobile communication system are provided. In a transmitter, an encoder encodes input information data and outputs systematic bits on a first channel and redundancy bits on a second channel. A first channel interleaver interleaves the systematic bits and a second channel interleaver interleaves the redundancy bits. A modulator maps one channel data of I and Q channel data, received from the first channel interleaver and another channel data of the I and Q channel data, received from the second channel interleaver to a modulation symbol using different mapping rules for I and Q channels.

### PRIORITY

This application claims priority under 35 U.S.C. § 119 to an application entitled “Transmitting/Receiving Apparatus and Method in a Mobile Communication System” filed in the Korean Intellectual Property Office on Jun. 9, 2005 and assigned Serial No. 2005-49178, the contents of which are herein incorporated by reference.

### BACKGROUND OF THE INVENTION

1. Field of the Invention

The present invention relates generally to a mobile communication system, and in particular, to a transmitting/receiving apparatus and method.

2. Description of the Related Art

Quadrature Amplitude Modulation (QAM) is a modulation technique in which a digital signal is broken up into each group having a predetermined number of bits and modulated using different carriers and phase shifts. Since QAM uses both phase and amplitude as variables, it advantageously carries a large amount of digital data simultaneously.

QAM carries two or more bits per symbol. The symbol can be expressed as two non-interfering numbers, i.e. a real number and an imaginary number as illustrated in Equation (1). Since the change of value x has no effect on value y, an in-phase (I-channel) signal component and a quadrature-phase (Q-channel) component correspond to x and y, respectively. Hence, the I and Q channels are a complex coordinates-representation of a sine wave.

16 QAM is chosen as an example. Referring to FIG. 10, a digital signal quantized to 16 levels is modulated to 16 coordinates of an I-Q plot. The radius denotes the signal amplitude and the angle from the I axis denotes the signal phase. Thus, 16 QAM has 16 signal points with different phases and amplitudes and carries 4 bits per signal point. A receiver demodulates the original signal by determining which area a received signal belongs to with respect to the boundary lines defining the 16 signal coordinates.

In QAM, every transmission bit does not have the same error probability during modulation. This error probability difference, called bit reliability, is a characteristic of QAM using Gray mapping. When transmission bits are mapped to symbols along a real-imaginary axis, the geometrical distances between the symbols are not equal. That's why the transmission bits differ in bit error probability.

Regarding the bit reliability in mathematical terms, the Log Likelihood Ratio (LLR) of each bit is computed by Equation (1)

$$r = x + j y \\ LLR ( b ) = ln [ \frac{Pr \{ b = 1 \text{\textbar} r \}}{Pr \{ b = 0 \text{\textbar} r \}} ] \qquad ( 1 )$$

where r denotes a received complex-number symbol and x and y denote an I-channel component and a Q-channel component, respectively output from a symbol demodulator. LLR(b) is the LLR of a transmitted bit b, calculated by the demodulator. For a channel decoder to decode through soft decision decoding, the demodulator must create a soft decision value corresponding to each channel-coded bit from a received two-dimensional signal composed of an I-channel component and a Q-channel component. An LLR calculated for each channel-coded bit is used as a soft decision value input to the channel decoder. Pr{A|B} is the conditional probability of an event A assuming that B has occurred. Hence, Pr{b=1|r} is the probability of the transmitted bit b being 1 when a symbol r has been received. Considering Gaussian noise probability, Equation (1) is expressed as Equation (2)

$$LLR ( {i}_{1} ) = ln [ \frac{{ⅇ}^{- {K ( x + {x}_{0} )}^{2}} + {ⅇ}^{- {K ( x + {x}_{1} )}^{2}}}{{ⅇ}^{- {K ( x - {x}_{0} )}^{2}} + {ⅇ}^{- {K ( x - {x}_{1} )}^{2}}} ] \\ LLR ( {i}_{2} ) = ln [ \frac{{ⅇ}^{- {K ( x - {x}_{1} )}^{2}} + {ⅇ}^{- {K ( x + {x}_{1} )}^{2}}}{{ⅇ}^{- {K ( x - {x}_{0} )}^{2}} + {ⅇ}^{- {K ( x - {x}_{0} )}^{2}}} ] \qquad ( 2 )$$

where LLR(iᵢ) is the estimated probability of a transmitted bit i₁ and LLR(i₂) is the estimated probability of a transmitted bit i₂. Because Equation (2) requires a relatively large amount of computation, an approximation algorithm for Equation (2) is needed for real implementation. Equation (2) is roughly approximated to Equation (3)
LLR(i₁)≈−4Kx₀x
LLR(i₂)≈−4Kx₀(2x₀−|x|) (3)

The mean LLR of each QAM symbol illustrated in FIG. 10 calculated by Equation (3) is shown in Table 1 below.

TABLE 1

| Symbol (i₁q₁i₂q₂) | Mean Value of x | Mean LLR (i₁) | Mean LLR (i₂) |
|---|---|---|---|
| 0q₁0q₂ | x₀ | −4Kx₀² = −λ | −4Kx₀² = −λ |
| 0q₁1q₂ | x₁ | −12Kx₀² = −3λ | 4Kx₀² = λ |
| 1q₁0q₂ | −x₀ | 4Kx₀² = λ | −4Kx₀² = −λ |
| 1q₁1q₂ | −x₁ | 12Kx₀² = 3λ | 4Kx₀² = λ |

As noted from Table 1, the LLRs of the bits of a received symbol are different depending on the location of an associated transmitted symbol, thus causing a difference in bit reliability.

Recently, studies have been conducted on methods relying on this QAM characteristic or methods for preventing the difference of bit reliability. It is known that an equal bit reliability among all data information bits leads to better transmission efficiency.

As an approach to achieving the same bit reliability among bits, a method has been proposed in which when a Hybrid Automatic Repeat request (HARQ) retransmission is performed in QAM, a different Gray mapping rule is applied to a retransmission symbol. HARQ, one of the error control techniques in a wireless environment, is a combination of a retransmission scheme for retransmitting an error—having data without correcting errors to increase data reception rate and an error correction channel coding scheme for correcting errors in received data. Conventionally, every bit achieves the same reliability after three retransmissions.

FIGS. 10 to 13 illustrate examples of Gray mapping for 16 QAM in a typical modulator. In 16 QAM, a code symbol sequence from a channel encoder is divided into each group having four bits and a 16 QAM constellation is comprised of 16 signal points. The code symbol sequence is mapped to particular signal points by Gray coding. In Gray coding, only one bit changes between subsequent numbers. Each quadrant includes four signal points. For example, the first quadrant is divided into four areas and “0001”, “0000”, “0011” and “0010” are mapped to upper left, lower left, upper right, and lower right areas, respectively. i1 denotes a location to which a 4-bit sequence with 1 as the first bit of the I channel is mapped and i2 denotes a location to which a 4-bit sequence with 1 as the second bit of the I channel is mapped. Similarly, q1 denotes a location to which a 4-bit sequence with 1 as the first bit of the q channel is mapped and q2 denotes a location to which a 4-bit sequence with 1 as the second bit of the q channel is mapped. As stated before, the I and Q channels are a complex coordinate-representation of a sine wave signal. A real-number axis corresponds to the I channel and an imaginary-number axis corresponds to the Q channel. In the illustrated cases of FIGS. 10 to 13, mapping is based on Gray coding and the same mapping rule applies to both the I and Q channels. For example, referring to FIG. 11, if the first and second bits of the I channel are mapped in the order “00”, “10”, “11” and “01”, the Q channel mapping follows the same rule. Thus, the first and second bits of the Q channel are mapped in the order “00”, “10”, “11” and “01”.

In the application of HARQ to FIGS. 10 to 13, the QAM signal constellation of FIG. 10 is used at an initial transmission, the QAM signal constellation of FIG. 11 is used at the first retransmission, the QAM signal constellation of FIG. 12 is used at the second retransmission, and the QAM signal constellation of FIG. 13 is used at the third retransmission. After the three retransmissions, therefore, every bit can achieve the same bit reliability.

However, the above technique is confined to HARQ and three retransmissions are not viable in real implementation. Accordingly, its real utilization and performance improvement is limited.

Meanwhile, repetition of bits before modulation may lead to a gain in a high Signal-to-Noise Ratio (SNR) and a high diversity gain on a fading channel due to a higher coding rate than in a conventional transmission method. A technique called Channel Symbol Expansion Diversity (CSED) utilizes this feature. The number of the resulting increased transmission bits can be matched to the same transmission rate by use of a higher-order modulation.

FIG. 1 is a block diagram of a conventional transmitter. Referring to FIG. 1, an encoder 101 encodes information bits to be transmitted at a predetermined coding rate R. If R is k/n, the encoder 101 encodes k-bit data to n bits. Notably, n and k are relatively prime. R can be ½, ¾, etc. Error recovery probability increases as R decreases. The coded sequence is divided into systematic bits and parity bits. The systematic bits are transmission information, and the parity bits are error correction information added to allow a receiver to correct errors that the transmission information may get during transmission, when decoding.

A channel interleaver 102 permutes the sequence of the coded bits to distribute burst errors caused by channel fading. The burst errors refer to errors concentrated on a specific part. A modulator 103 modulates the interleaved bits to symbols and sends them to the receiver via a transmit antenna.

The method to send two information bits will be described with reference to FIG. 3. Referring to FIG. 3, Quadrature Phase Shift Keying (QPSK) is adopted and R is ½ for sending a 2-bit signal 301. The two information bits 301 are encoded to a 4-bit signal 302 with two systematic bits and two parity bits by the encoder. The 4-bit coded signal 302 is interleaved by the interleaver and the interleaved bits 303 are modulated to two transmission symbols 304 by the modulator.

FIG. 2 is a block diagram of a conventional transmitter using CSED.

Referring to FIG. 2, for the input of information bits to be transmitted, an encoder 201 outputs coded data bits and a repeated version of the coded data bits. A channel interleaver 202 interleaves the coded data bits, and a channel interleaver 203 interleaves the repeated data bits. A modulator 204 maps every two interleaved data bits received from the channel interleavers 202 and 203 to a symbol by Gray mapping. Despite the increased number of transmission bits caused by the repetition, the same transmission rate can be achieved by a higher-order modulation.

Transmission of two information bits in CSED will be described now with reference to FIG. 3, in which 16 QAM is used and R is ½. Two information bits 305 are encoded to a 4-bit coded signal 306 by the encoder. In addition, the encoder outputs a repetition 307 of the coded signal 306 to achieve diversity effects in CSED. Hence, two 4-bit signals, i.e. an 8-bit signal is output. The two 4-bit signals are interleaved by the different interleavers, as indicated by reference numeral 308 and modulated to two 16 QAM symbols 309 by the modulator. Since CSED carries more data bits per symbol at the same transmission rate as in the typical transmission scheme, it is more effective.

In a real channel environment, however, error probability increases with a modulation order and thus it is difficult to achieve a gain with CSED, compared to the typical transmission scheme. Moreover, in view of the QAM nature of non-uniform bit reliability, simple repetition is likely to increase the reliability difference between data bits. In other words, since both coded data bits and repeated data bits may be allocated to higher-reliability locations, performance gain cannot be expected in the real channel environment.

### SUMMARY OF THE INVENTION

An object of the present invention is to substantially solve at least the above problems and/or disadvantages and to provide at least the advantages below. Accordingly, an object of the present invention is to provide a transmitting/receiving apparatus and method for achieving performance gain, taking into account bit reliability in a mobile communication system.

Another object of the present invention is to provide a transmitting/receiving apparatus and method for producing an equal bit reliability between information data bits by applying different mapping rules to the I and Q channels in a mobile communication system.

According to one aspect of the present invention, in a transmitter, an encoder encodes input information data and outputs systematic bits on a first channel and redundancy bits on a second channel. A first channel interleaver interleaves the systematic bits and a second channel interleaver interleaves the redundancy bits. A modulator maps one channel data of I and Q channel data, received from the first channel interleaver and another channel data of the I and Q channel data, received from the second channel interleaver to a modulation symbol using different mapping rules for 1 and Q channels.

According to another aspect of the present invention, in a receiver, a demodulator demodulates a received symbol to I-channel data and Q-channel data by applying different mapping rules for I and Q channels. A first channel deinterleaver deinterleaves one channel data of the I-channel and Q-channel data, received from the demodulator and outputs the deinterleaved data as systematic bits. A second channel deinterleaver deinterleaves another channel data of the I-channel and Q-channel data, received from the demodulator and outputs the deinterleaved data as redundancy bits. A decoder decodes the systematic bits and the redundancy bits to an original information bit stream.

According to a further aspect of the present invention, in a transmission method, input information data is encoded and systematic bits and redundancy bits are output on first and second channels, respectively. The systematic bits and redundancy bits are interleaved by first and second channel interleavers, respectively. One first-channel interleaved data of I and Q channel data and another second-channel interleaved data of the I and Q channel data are mapped to a modulation symbol using different mapping rules for I and Q channels.

According to still another aspect of the present invention, in a reception method, a received symbol is demodulated to I-channel data and Q-channel data by applying different mapping rules for I and Q channels. One channel data of the I-channel and Q-channel data is deinterleaved and output as systematic bits, while another channel data of the I-channel and Q-channel data is deinterleaved and output as redundancy bits. The systematic bits and the redundancy bits are decoded to an original information bit stream.

According to still further aspect of the present invention, in a transmitter, an encoder encodes input information data and outputs systematic bits on a first channel, first redundancy bits on a second channel, and second redundancy bits alternately on the first and second channels. A first channel interleaver interleaves the systematic bits and the second redundancy bits received on the first channel, and a second channel interleaver interleaves the first and second redundancy bits received on the second channel. A modulator maps one channel data of I and Q channel data, received from the first channel interleaver and another channel data of the I and Q channel data, received from the second channel interleaver to a modulation symbol using different mapping rules for I and Q channels.

According to yet another aspect of the present invention, in a receiver, a demodulator demodulates a received symbol to I-channel data and Q-channel data by applying different mapping rules for I and Q channels. A first channel deinterleaver deinterleaves one channel data of the I-channel and Q-channel data, received from the demodulator and outputs the deinterleaved data as systematic bits and second redundancy bits. A second channel deinterleaver deinterleaves another channel data of the I-channel and Q-channel data, received from the demodulator and outputs the deinterleaved data as first and second redundancy bits. A decoder decodes the systematic bits and the first and second redundancy bits to an original information bit stream.

According to yet further aspect of the present invention, in a transmission method, input information data is encoded and systematic bits is output on a first channel, first redundancy bits on a second channel, and second redundancy bits alternately on the first and second channels. The systematic bits and the second redundancy bits received on the first channel are interleaved by a first channel interleaver. The first and second redundancy bits received on the second channel are interleaved by a second channel interleaver. One first-channel interleaved data of I and Q channel data and another second-channel interleaved data of the I and Q channel data are mapped to a modulation symbol using different mapping rules for I and Q channels.

According to yet still another aspect of the present invention, in a reception method, a received symbol is demodulated to I-channel data and Q-channel data by applying different mapping rules for I and Q channels. One channel data of the I-channel and Q-channel data is deinterleaved and output as systematic bits and second redundancy bits. Another channel data of the I-channel and Q-channel data is deinterleaved and output as first and second redundancy bits. The systematic bits and the first and second redundancy bits are decoded to an original information bit stream.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram of a conventional transmitter;

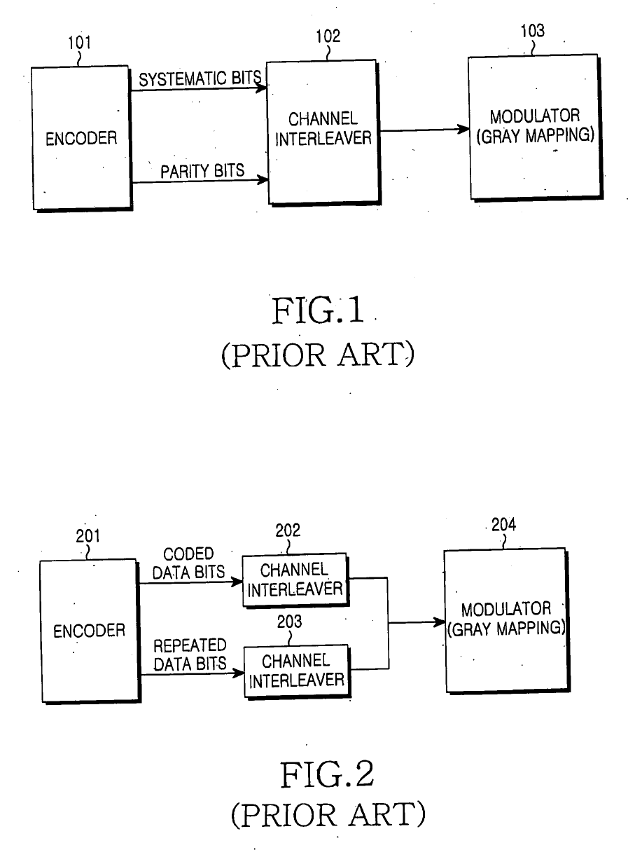

FIG. 2 is a block diagram of a conventional transmitter using CSED;

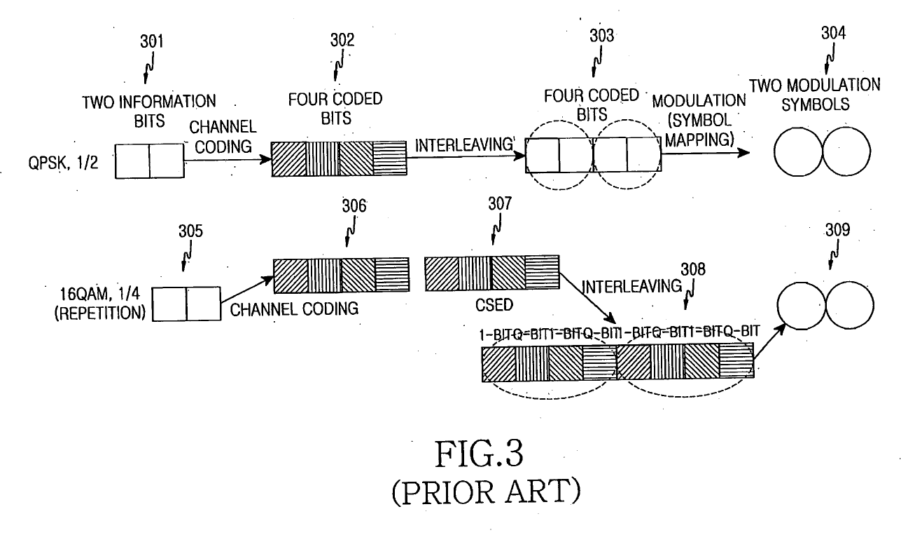

FIG. 3 illustrates transmission of two information bits from the transmitters illustrated in FIGS. 1 and 2;

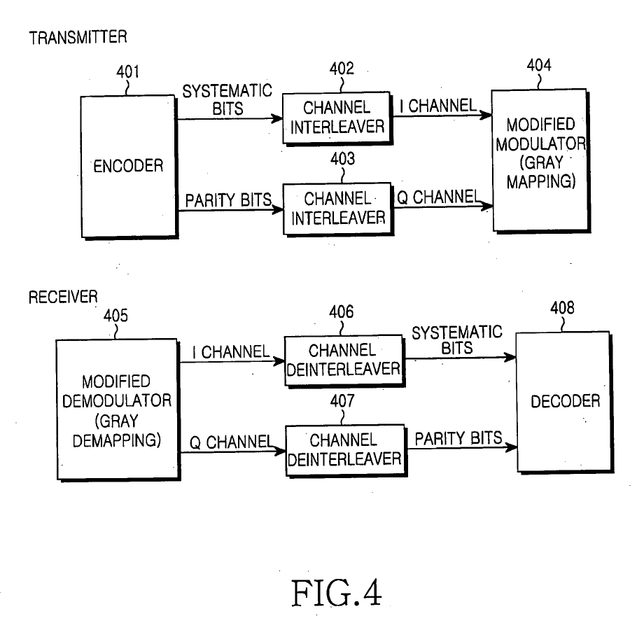

FIG. 4 is a block diagram of a transmitter and a receiver according to a first embodiment of the present invention;

FIG. 5 is a block diagram of a transmitter and a receiver according to a second embodiment of the present invention;

FIG. 6 illustrates transmission of two information bits from the transmitter illustrated in FIG. 5;

FIG. 7 illustrates interleaving according to the present invention;

FIG. 8 is a block diagram of a transmitter and a receiver according to a third embodiment of the present invention;

FIG. 9 is a block diagram of a transmitter and a receiver according to a fourth embodiment of the present invention;

FIGS. 10 to 13 illustrate examples of Gray mapping for 16 QAM in a typical modulator;

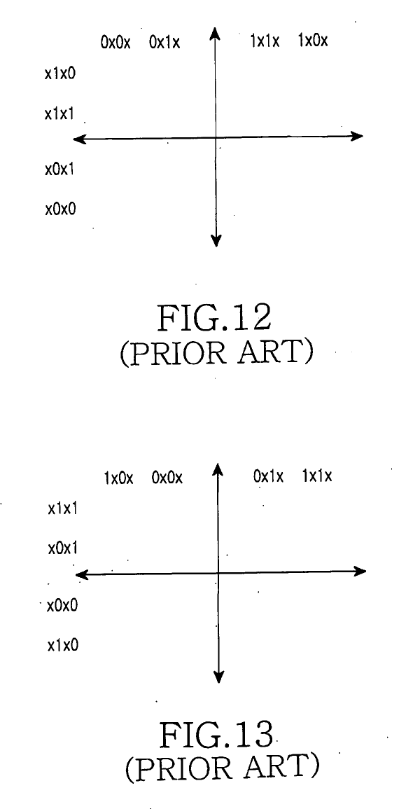

FIGS. 14 and 15 illustrate examples of Gray mapping for 16 QAM in a modified modulator according to the present invention;

FIG. 16 is a flowchart illustrating a transmission procedure in the transmitter according to the present invention;

FIG. 17 is a flowchart illustrating a reception procedure in the receiver according to the present invention; and

FIG. 18 is a graph comparing a simulated conventional CSED with a simulated CSED of the present invention in terms of performance.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

Conventional modulation and demodulation schemes give no regard to a difference in bit reliability in a transmitter and a receiver. In the presence of a repeated bit stream as in CSED, therefore, the difference of bit reliability is further increased. Accordingly, there exists a need for applying a different mapping rule from that of the original bits to the repeated bits.

The present invention provides a method of achieving an equal bit reliability among the original information data bits by allocating the original bits and their repeated bits to different real-number and imaginary-number (I-channel and Q-channel) axes and applying different mapping rules to the axes.

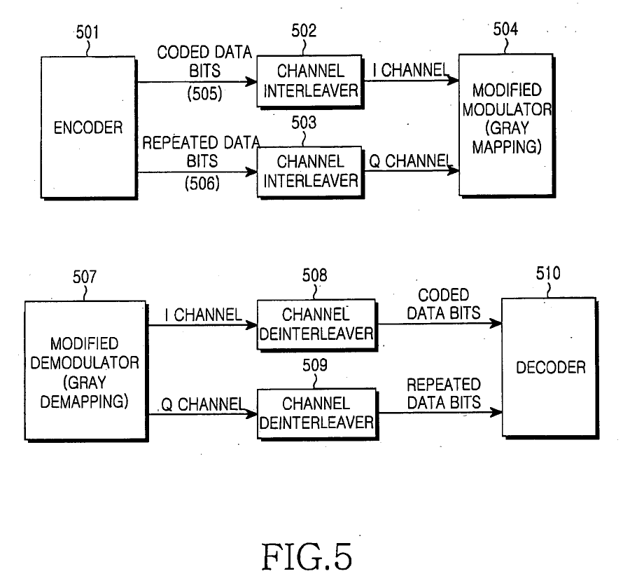

FIG. 4 is a block diagram of a transmitter and a receiver using a typical channel encoding scheme according to a first embodiment of the present invention. The typical encoding scheme can be a rate ½ convolutional code or Low Parity Density Check (LDPC) code. According to the channel coding scheme, parity bits carry information about associated systematic bits so that when the information bits have errors, they can be recovered only with the parity bits. Thus, since it can be said that there is repetitiveness between the systematic bits and the parity bits, they can be applied to the present invention.

Referring to FIG. 4, in the transmitter, an encoder 401 encodes information bits to be transmitted. The coded bits are divided into systematic bits and parity bits. The systematic bits are transmission information itself and the parity bits are additional error correction information by which a receiver corrects transmission errors during decoding. The systematic bits are allocated to the I channel and the parity bits to the Q channel, or vice versa. Channel interleavers 402 and 403 channel-interleave the systematic bits and the parity bits, respectively, in order to distribute burst errors caused by channel fading. A modified modulator 404 maps the interleaved bits to symbols by using different Gray mapping rules to the I and Q channels. Consequently, the receiver acquires an estimate with a uniform reliability across bits, for of a transmitted signal.

In the receiver, a modified demodulator 405 demodulates symbol data received at the receiver according to the demapping rules of the I and Q channels. The demodulated data bits are separated into the I and Q channels and provided to channel deinterleavers 406 and 407. The channel deinterleavers 406 and 407 deinterleave the I and Q channels, respectively. A decoder 408 decodes systematic bits resulting from the I-channel deinterleaving and parity bits resulting from the Q-channel deinterleaving, and determines final received information data bits. In this way, the receiver receives QAM symbols each having a uniform bit reliability.

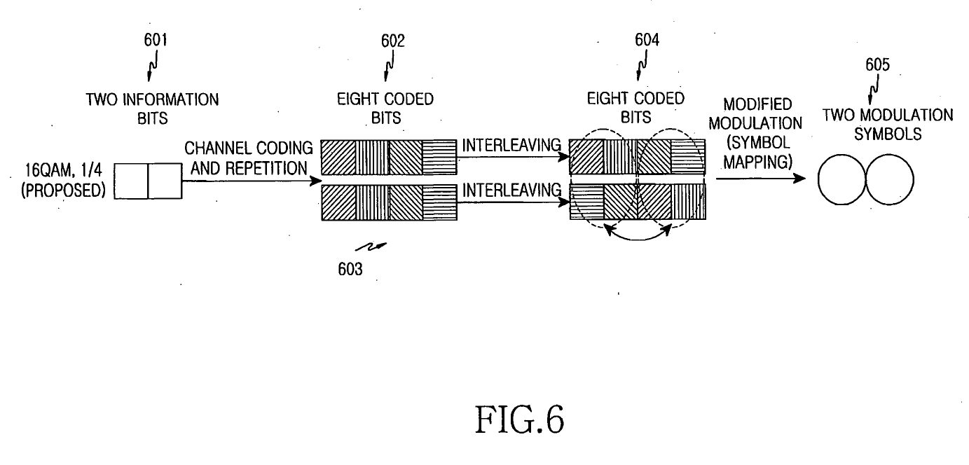

FIG. 5 is a block diagram of a transmitter and a receiver using CSED according to a second embodiment of the present invention.

Referring to FIG. 5, in the transmitter, an encoder 501 encodes information bits to be transmitted. Along with the coded data bits 505, the encoder 501 also outputs a repetition 506 of the coded data bits 505. The coded data bits 505 are allocated to the I channel and the repeated data bits 506 are allocated to the Q channel, or vice versa. Channel interleavers 502 and 503 interleave the coded data bits 505 and the repeated data bits 506, respectively. A modified modulator 504 modulates the interleaved data bits to symbols using different Gray mapping rules for the I and Q channels. In this way, the transmitter maps the coded data bits 505 and the repeated data bits 506 to locations with different bit reliabilities.

In the receiver, a modified demodulator 507 demodulates the received coded data bits and repeated data bits according to different demapping rules for the I and Q channels. The demodulated data bits are separated into the I and Q channels and provided to channel deinterleavers 508 and 509, respectively. The channel interleavers 508 and 509 deinterleave the demodulated signals. A decoder 510 decodes the deinterleaved I-channel coded data bits and the deinterleaved Q-channel repeated data bits, thus deciding final received information data bits. The information data bits have a uniform bit reliability.

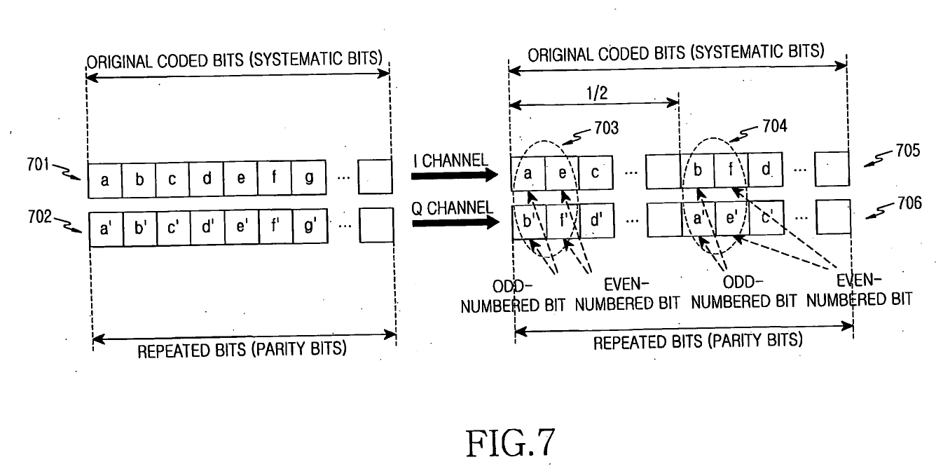

FIG. 6 illustrates transmission of two information bits from the transmitter illustrated in FIG. 5, in which 16 QAM is used and R is ½.

Referring to FIG. 6, for the input of two information bits 601, the encoder outputs a 4-bit coded signal 602. According to CSED, the encoder additionally repeats the coded signal 602 and thus outputs the four coded bits 602 and the four repeated bits 603 simultaneously. The coded signal 602 is allocated to the I channel and then interleaved, and the repeated signal 603 is allocated to the Q channel and then interleaved, or vice versa. The modified modulator extracts two bits from the I channel and two bits from the Q channel and maps them to a symbol 605 by Gray mapping 604. In this way, the receiver receives information data bits with a uniform bit reliability.

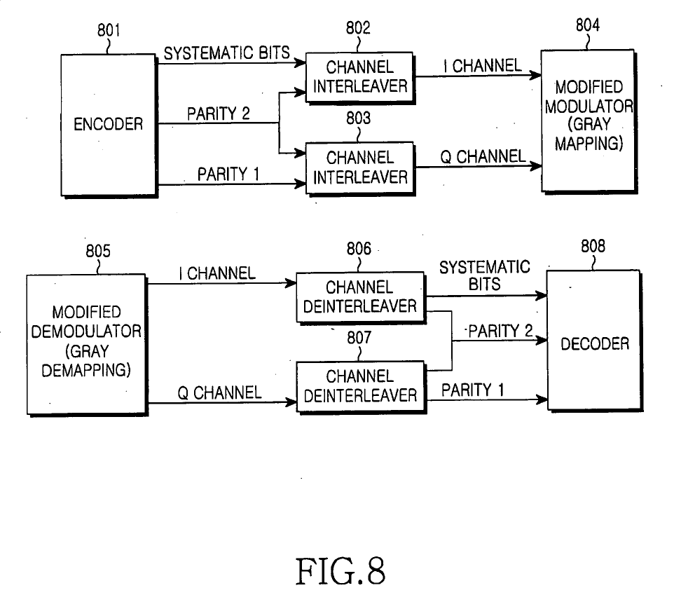

FIG. 7 illustrates interleaving according to the present invention. An original coded bit stream and its repeated bit stream are interleaved such that interleaved bits of the two streams to be modulated at the same time are arranged at the same positions on the I and Q channels.

Referring to FIG. 7, first and second interleavers interleave an original coded bit stream 701 of the I channel and a repeated bit stream 702 of the Q channel in the same pattern. The interleaved bits of the Q channel are cyclically shifted by half the channel length, prior to input to a modified modulator. Reference numerals 705 and 706 denote the interleaved original coded bit stream and the cyclic-shifted repeated bit stream, respectively. Therefore, bit “a” is sent at the first position of the I channel in a first symbol 703, and its repeated bit (or parity bit) “a” is sent at the first position of the Q channel in a different symbol 704. This transmission pattern maximized diversity gain because a predetermined distance is maintained between an original bit and its parity bit.

The above-described embodiments describe the case where the number of originally coded bits is equal to that of their repeated bits. Hence, they apply to CSED or a rate ½ convolutional code and LDPC code. On the other hand, for a turbo code, an internal interleaver exists in a turbo encoder and thus a distinction cannot be made between a systematic bit and a parity bit. Hence, when there is no clear distinction between a systematic bit and a parity bit or R is not ½, some modifications are required.

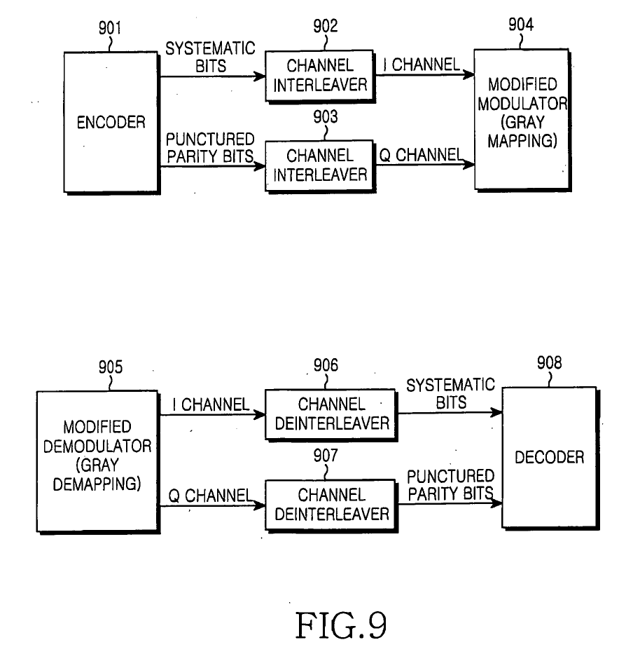

FIG. 8 is a block diagram of a transmitter and a receiver using a turbo code according to a third embodiment of the present invention, in which a mother coding rate is ⅓ and a coding rate is ⅓ for the turbo code.

Referring to FIG. 8, in the transmitter, an encoder 801 creates systematic bits, first parity bits (parity 1), and second parity bits (parity 2) by encoding information bits to be transmitted and outputs the systematic bits on the I channel and parity 1, which was not interleaved within the encoder 801, on the Q channel, considering parity 1 is a repetition of the systematic bits. The encoder 801 allocates parity 2 to the I and Q channels alternately. For example, it allocates odd-numbered bits of parity 2 to the I channel and even-numbered bits of parity 2 to the Q channel. A channel interleaver 802 interleaves the systematic bits and alternately selected bits of parity 2, and a channel interleaver 803 interleaves parity 1 and the remaining bits of parity 2. A modified modulator 804 extracts two bits from the I channel and two bits from the Q channel and modulates them by Gray mapping. Thus, performance gain is expected even in the case of a mother coding rate of ⅓.

In the receiver, a modified demodulator 805 demodulates a received symbol using different demapping rules for the I and Q channels and transmits the demodulated symbol on the I and Q channels. A channel deinterleaver 806 interleaves the I-channel symbol and outputs a systematic bit and parity 2, while a channel deinterleaver 807 interleaves the Q-channel symbol and outputs parity 1 and parity 2. A decoder 808 generates information data from the systematic bit, parity 1, and parity 2.

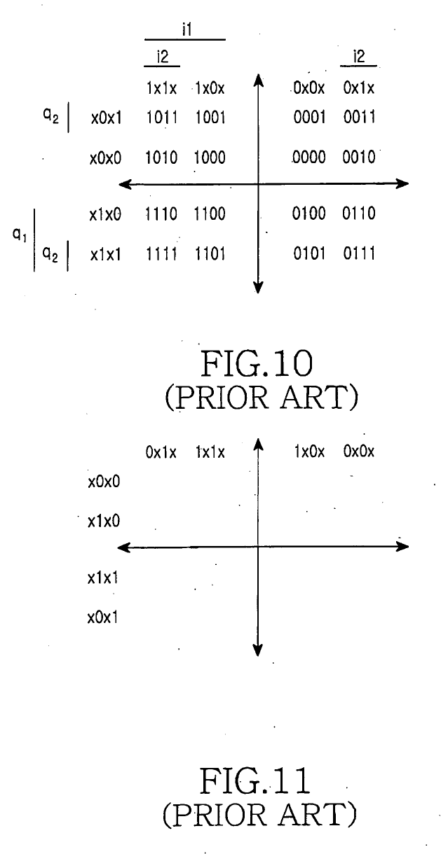

FIG. 9 is a block diagram of a transmitter and a receiver using a turbo code according to a fourth embodiment of the present invention, in which the mother coding rate and effective coding rate of the turbo code is ⅓ and ½, respectively.

Referring to FIG. 9, in the transmitter, an encoder allocates a systematic bit to the I channel and allocates parity 1 and parity 2 which are alternately punctured to the Q channel. The puncturing is performed for matching the number of transmission bits to an intended coding rate. Channel interleavers 902 and 903 interleave the data bits of the I and Q channels. A modified modulator 904 extracts two bits from the I channel and two bits from the Q channel and maps them to a modulation symbol by Gray mapping.

In the receiver, a modified demodulator 905 demodulates a received symbol using different demapping rules for the I and Q channels and transmits the demodulated symbol on the I and Q channels. A channel deinterleaver 906 interleaves the I-channel demodulated symbol and outputs a systematic bit, while a channel deinterleaver 907 interleaves the Q-channel demodulated symbol and outputs parity bits. A decoder 908 generates information data using the systematic bit, parity 1, and parity 2.

In the structures in FIGS. 8 and 9, the internal interleaver of the turbo encoder is so configured as to permute the sequences of bits of the I and Q channels in the same pattern in order to prevent a change in bit positions within each symbol. For example, in 16 QAM, two bits are allocated to the Q channel. For parity 2, which is subject to internal interleaving, the internal interleaver interleaves odd-numbered bits and even-numbered bits, independently in the same pattern, so that they are not mixed.

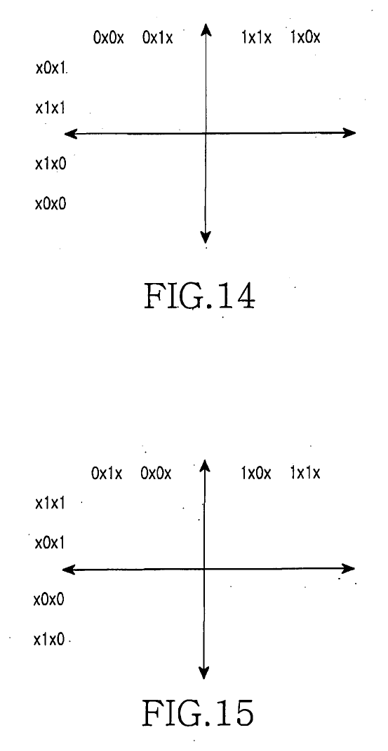

FIGS. 14 and 15 illustrate examples of Gray mapping for 16 QAM in a modified modulator according to the present invention. While the I and Q channel are based on a basic Gray mapping rule, there are different bit reliability distributions along the real-number axis and the imaginary-number axis. Referring to FIG. 14, different mapping rules apply to the I and Q channels, for modulation, such that the first and second bits of the I channel are mapped in the order of “10”, “11”, “01” and “00” and the first and second bits of the Q channel are mapped in the order of “01”, “11”, “10” and “00”. Since an original coded signal and its repetition are allocated to different locations on the I and Q channels, the I and Q channel have different bit reliability distributions. As a consequence, each data bit has a uniform reliability.

In application to HARQ, when the QAM constellations of FIGS. 14 and 15 are used at an initial transmission and a retransmission, respectively, every bit has the exact same bit reliability just after one retransmission. Therefore, the present invention outperforms the conventional technology in which the same reliability is achieved after three retransmissions using the afore-mentioned four QAM mapping rules.

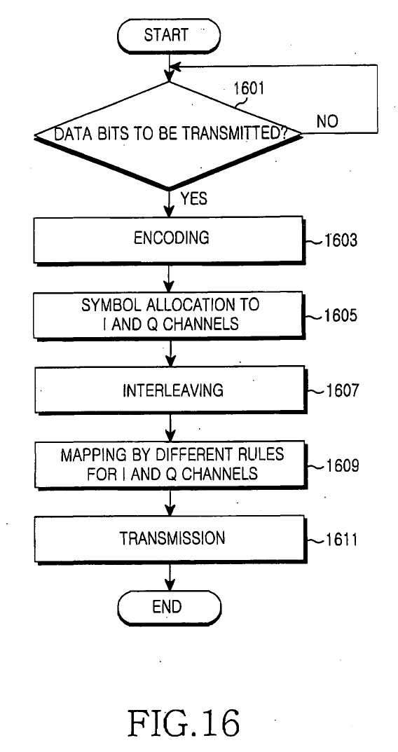

FIG. 16 is a flowchart illustrating a transmission procedure in the transmitter according to the present invention.

Referring to FIG. 16, the transmitter monitors presence or absence of information data bits to be transmitted in step 1601. In the presence of information data bits, the transmitter encodes them in step 1603 and allocates the code symbol to the I and Q channels in step 1605. When the transmitter operates typically, the encoder outputs systematic bits and parity bits. When the transmitter uses CSED, the encoder outputs coded data bits and repeated data bits. If a rate ½ convolutional code or LDPC code is used, the encoder allocates the systematic bits and the parity bits to the I and Q channels, respectively. In case of CSED, the encoder allocates the coded data bits and the repeated data bits to the I and Q channels, respectively. If a turbo code with a mother coding rate of ⅓ and a coding rate of ⅓ is used, systematic bits and odd-numbered bits of parity 2 are allocated to the I channel and parity 1 and even-numbered bits of parity 2 are allocated to the Q channel. If a turbo code with a mother coding rate of ⅓ and an effective coding rate of ½ is used, systematic bits are allocated to the I channel, and parity bits punctured for matching to the coding rat are allocated to the Q channel.

In step 1607, the transmitter interleaves the code symbols of the I and Q channels in respective channel interleavers. The transmitter then maps the interleaved bits to signal points using different mapping rules for the I and Q channels in step 1609, transmits the modulation symbols in step 1611, and then ends the process of the present invention.

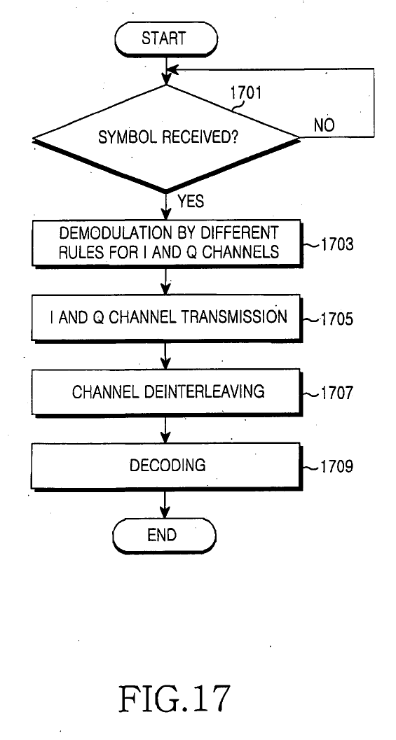

FIG. 17 is a flowchart illustrating a reception procedure in the receiver according to the present invention.

Referring to FIG. 17, the receiver monitors reception of a symbol in step 1701. Upon receipt of a symbol, the receiver demodulates the symbol using different demapping rules of the I and Q channels in step 1703. In step 1705, the receiver sends the demodulated symbol separately on the I and Q channels. The receiver deinterleaves the I- and Q-channel demodulation symbols in channel deinterleavers in step 1707 and combines the deinterleaved bits, for decoding in step 1709. After deciding final received information data bits, the receiver ends the algorithm of the present invention.

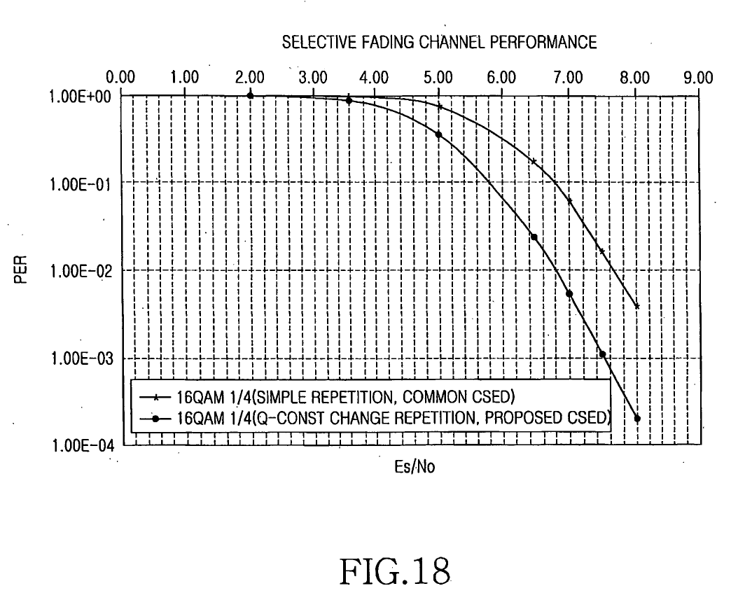

FIG. 18 is a graph comparing simulation results of the conventional CSED and the inventive CSED in terms of performance. The simulation conditions are that the coding rate is 1.4 and 16 QAM is adopted. The simulation reveals that the inventive CSED outperforms the conventional CSED in terms of transmission performance. For instance, the present invention achieves an about 0.8-dB increase in SNR Eₛ/Nₒ at a Packet Error Rate (PER) of 10⁻² and a PER decrease from 10⁻¹ to 10⁻² at Eₛ/Nₒ=6.8 dB. The simulations were performed for an Orthogonal Frequency Division Multiplexing (OFDM) communication system using a 5 GHz band under a Rayleigh fading channel environment.

As described above, the present invention uses a modulation/demodulation scheme considering bit reliability in a mobile communication system. In case of using repeated bits as in CSED, original bits and their repetition are allocated to real-number and imaginary-number axes (I and Q channels), respectively, and different mapping rules are applied to the axes. Therefore, a uniform bit reliability is achieved among the original information data bits without an additional hardware configuration. Since diversity gain is achieved by repetition of the same signal or by utilizing the repetitiveness of parity bits with respect to systematic bits, a larger gain is possible in a variable channel condition and on a fast fading channel or a highly frequency-selective channel. Hence, a higher efficiency than in a typical QAM transmission system can be achieved and an excellent communication system can be configured.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A transmitter comprising:
an encoder for encoding input information data and outputting systematic bits on a first channel and redundancy bits on a second channel;
a first channel interleaver for interleaving the systematic bits;
a second channel interleaver for interleaving the redundancy bits; and
a modulator for mapping one channel data of I and Q channel data received from the first channel interleaver, and another channel data of the I and Q channel data received from the second channel interleaver, to a modulation symbol using different mapping rules for I and Q channels.

2. The transmitter of claim 1, wherein the systematic bits are original information bits and the redundancy bits are parity bits.

3. The transmitter of claim 1, wherein the systematic bits are a code symbol sequence and the redundancy bits are a repetition of the code symbol sequence.

4. The transmitter of claim 1, wherein the encoder is one of a convolutional encoder, a Low Density Parity Check (LDPC) encoder, a turbo encoder, and a Channel Symbol Expansion Diversity (CSED) encoder.

5. The transmitter of claim 1, wherein the mapping rules are Gray mapping rules.

6. The transmitter of claim 1, wherein the second channel interleaver interleaves the redundancy bits in a same pattern as used in the first channel interleaver and circularly shifts the interleaved bits by a predetermined length.

7. A receiver comprising:
a demodulator for demodulating a received symbol to I-channel data and Q-channel data using different demapping rules for I and Q channels;
a first channel deinterleaver for deinterleaving one channel data of the I-channel and Q-channel data received from the demodulator, and outputting the deinterleaved data as systematic bits;
a second channel deinterleaver for deinterleaving another channel data of the I-channel and Q-channel data received from the demodulator, and outputting the deinterleaved data as redundancy bits; and
a decoder for decoding the systematic bits and the redundancy bits to an original information bit stream.

8. The receiver of claim 7, wherein the systematic bits are original information bits and the redundancy bits are parity bits.

9. The receiver of claim 7, wherein the systematic bits are a code symbol sequence and the redundancy bits are a repetition of the code symbol sequence.

10. The receiver of claim 7, wherein the decoder is one of a convolutional decoder, a Low Density Parity Check (LDPC) decoder, a turbo decoder, and a Channel Symbol Expansion Diversity (CSED) decoder.

11. The receiver of claim 7, wherein the demapping rules are Gray demapping rules.

12. The receiver of claim 7, wherein the second channel deinterleaver deinterleaves the channel data in a same pattern as used in the first channel deinterleaver and circularly shifts the deinterleaved bits by a predetermined length.

13. A transmission method comprising the steps of:
encoding input information data and outputting systematic bits on a first channel and redundancy bits on a second channel;
interleaving the systematic bits by a first channel interleaver;
interleaving the redundancy bits by a second channel interleaver; and
mapping one first-channel interleaved data of I and Q channel data and another second-channel interleaved data of the I and Q channel data to a modulation symbol using different mapping rules for I and Q channels.

14. The transmission method of claim 13, wherein the systematic bits are original information bits and the redundancy bits are parity bits.

15. The transmission method of claim 13, wherein the systematic bits are a code symbol sequence and the redundancy bits are a repetition of the code symbol sequence.

16. The transmission method of claim 13, wherein the coding is one of convolutional coding, Low Density Parity Check (LDPC) coding, turbo encoding, and Channel Symbol Expansion Diversity (CSED) coding.

17. The transmission method of claim 13, wherein the mapping rules are Gray mapping rules.

18. The transmission method of claim 13, wherein the second channel interleaver interleaves the redundancy bits in a same pattern as used in the first channel interleaver and circularly shifts the interleaved bits by a predetermined length.

19. A reception method comprising the steps of:
demodulating a received symbol to I-channel data and Q-channel data using different demapping rules for I and Q channels;
deinterleaving one channel data of the I-channel and Q-channel data and outputting the deinterleaved bits as systematic bits;
deinterleaving another channel data of the I-channel and Q-channel data and outputting the deinterleaved bits as redundancy bits; and
decoding the systematic bits and the redundancy bits to an original information bit stream.

20. The reception method of claim 19, wherein the systematic bits are original information bits and the redundancy bits are parity bits.

21. The reception method of claim 19, wherein the systematic bits are a code symbol sequence and the redundancy bits are a repetition of the code symbol sequence.

22. The reception method of claim 19, wherein the decoding is one of convolutional decoding, Low Density Parity Check (LDPC) decoding, turbo decoding, and Channel Symbol Expansion Diversity (CSED) decoding.

23. The reception method of claim 19, wherein the demapping rules are Gray demapping rules.

24. The reception method of claim 19, wherein one of the channel deinterleaving steps further comprises deinterleaving the channel data in a same pattern as used for the other channel data and circularly shifting the deinterleaved bits by a predetermined length.

25. A transmitter comprising:
an encoder for encoding input information data and outputting systematic bits on a first channel, first redundancy bits on a second channel, and second redundancy bits alternately on the first and second channels;
a first channel interleaver for interleaving the systematic bits and the second redundancy bits received on the first channel;
a second channel interleaver for interleaving the first and second redundancy bits received on the second channel; and
a modulator for mapping one channel data of I and Q channel data, received from the first channel interleaver and another channel data of the I and Q channel data, received from the second channel interleaver to a modulation symbol using different mapping rules for I and Q channels.

26. The transmitter of claim 25, wherein the systematic bits are original information bits and the redundancy bits are parity bits.

27. The transmitter of claim 25, wherein the encoder is a turbo encoder.

28. The transmitter of claim 25, wherein the mapping rules are Gray mapping rules.

29. The transmitter of claim 25, wherein the second channel interleaver interleaves the first and second redundancy bits in a same pattern as used in the first channel interleaver and circularly shifts the interleaved bits by a predetermined length.

30. A receiver comprising:
a demodulator for demodulating a received symbol to I-channel data and Q-channel data using different demapping rules for I and Q channels;
a first channel deinterleaver for deinterleaving one channel data of the I-channel and Q-channel data received from the demodulator, and outputting the deinterleaved data as systematic bits and second redundancy bits;
a second channel deinterleaver for deinterleaving another channel data of the I-channel and Q-channel data received from the demodulator, and outputting the deinterleaved data as first and second redundancy bits; and
a decoder for decoding the systematic bits and the first and second redundancy bits to an original information bit stream.

31. The receiver of claim 30, wherein the systematic bits are original information bits and the redundancy bits are parity bits.

32. The receiver of claim 30, wherein the decoder is a turbo decoder.

33. The receiver of claim 30, wherein the demapping rules are Gray demapping rules.

34. The receiver of claim 30, wherein the second channel deinterleaver deinterleaves the channel data in a same pattern as used in the first channel deinterleaver and circularly shifts the deinterleaved bits by a predetermined length.

35. A transmission method comprising the steps of:
encoding input information data and outputting systematic bits on a first channel, first redundancy bits on a second channel, and second redundancy bits alternately on the first and second channels;
interleaving the systematic bits and the second redundancy bits received on the first channel by a first channel interleaver;
interleaving the first and second redundancy bits received on the second channel by a second channel interleaver; and
mapping one first-channel interleaved data of I and Q channel data and another second-channel interleaved data of the I and Q channel data to a modulation symbol using different mapping rules for I and Q channels.

36. The transmission method of claim 35, wherein the systematic bits are original information bits and the redundancy bits are parity bits.

37. The transmission method of claim 35, wherein the encoding is turbo encoding.

38. The transmission method of claim 35, wherein the mapping rules are Gray mapping rules.

39. The transmission method of claim 35, wherein the second channel interleaver interleaves the first and second redundancy bits in a same pattern as used in the first channel interleaver and circularly shifts the interleaved bits by a predetermined length.

40. A reception method comprising the steps of:
demodulating a received symbol to I-channel data and Q-channel data using different demapping rules for I and Q channels;
deinterleaving one channel data of the I-channel and Q-channel data and outputting the deinterleaved data as systematic bits and second redundancy bits;
deinterleaving another channel data of the I-channel and Q-channel data and outputting the deinterleaved data as first and second redundancy bits; and
decoding the systematic bits and the first and second redundancy bits to an original information bit stream.

41. The reception method of claim 40, wherein the systematic bits are original information bits and the redundancy bits are parity bits.

42. The reception method of claim 40, wherein the decoding is turbo decoding.

43. The reception method of claim 40, wherein the demapping rules are Gray demapping rules.

44. The reception method of claim 40, wherein one of the deinterleaving steps comprises deinterleaving the channel data in a same pattern as used for the other channel data and circularly shifting the deinterleaved bits by a predetermined length.
